(19) United States
(12) Patent Application Publication
(10) Pub. No.: US 2007/0269587 A1
(43) Pub. Date: Nov. 22, 2007

(54) Film formation source, vacuum film formation apparatus, organic el panel and method of manufacturing the same

(75) Inventors: Daisuke Masuda, Tokyo (JP); Hirosi Abiko, Tokyo (JP); Shigehiro Umetsu, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOHOKU PIONEER CORPORATION, Tendo-shi (JP)

(21) Appl. No.: 11/715,461

(22) Filed: Mar. 8, 2007

Related U.S. Application Data
(62) Division of application No. 11/139,802, filed on May 31, 2005, now abandoned.

(30) Foreign Application Priority Data
Jun. 1, 2004 (JP) 2004-163413

(51) Int. Cl. B05D 5/06; B05D 5/12

(52) U.S. Cl. 427/66; 445/24

(57) ABSTRACT

A film formation source of a vacuum film formation apparatus for forming thin film on the film formation surface of a substrate includes a material accommodating unit containing a film formation material; a heater for heating the film formation material contained within the material accommodating unit; and a film formation flow control unit provided at an emission outlet of the material accommodating unit for controlling the direction of the film formation flow. The film formation flow control unit provides a strong directivity to the film formation flow with respect to the moving direction of the film formation surface relative to the film formation source.

### CROSS REFERENCE TO RELATED APPLICATIONS

The present Application is a Divisional Application of U.S. patent application Ser. No. 11/139,802, filed on May 31, 2005.

### BACKGROUND OF THE INVENTION

The present invention relates to film formation source, vacuum film formation apparatus, organic EL panel and method of manufacturing the same.

The present application claims priority from Japanese Application No. 2004-163413, the disclosure of which is incorporated herein by reference.

A film formation method such as vapor deposition, sputtering, and molecular beam epitaxy and the like usually employs a single one fixed film formation source. However, none of these methods is suitable for treating a substrate having a relatively large area. This is because a large size substrate makes it necessary to enlarge a film formation area by enlarging the scale of a film formation source or increasing a distance between the substrate and the film formation source, hence resulting in an increase in the size of the film formation apparatus. Moreover, if the substrate and a mask are brought close to each other in order to inhibit material consumption, film formation materials entering shielding portions of the mask are likely to cause a film formation defect, resulting in a low pattern formation precision and thus causing an un-uniform distribution of film thickness.

In recent years, organic EL device has been used as self-emission type thin display device or as surface emission source which has attracted considerable attention in the field of display and illumination. Each organic EL device has a basic structure comprising a first electrode formed on a substrate, an organic layer consisting of organic compound and formed on the first electrode, and a second electrode formed on the organic layer. Here, a film formation step for forming the organic layer is realized by using a film formation method such as vacuum vapor deposition. However, in a process of manufacturing such organic EL device, if the scale of the film formation source is increased in order to treat a large size substrate, a further problem will occur which shows that if an organic compound material exhibits a low thermal conductivity, it is difficult to ensure a uniform vapor deposition flow, making it impossible to realize a uniform film formation and thus reducing the function of the organic layer.

In order to cope with the aforementioned problem, Japanese Unexamined Patent Application Publication No. 2001-247959 has suggested an arrangement shown in FIG. 1A. As shown, a vapor deposition source 2 including a plurality of vapor deposition cells 2a arranged in the longitudinal direction thereof is disposed with respect to a substrate 1, and moved in a direction (shown by arrows) perpendicular to the longitudinal direction of the vapor deposition source so as to form a thin film T on the substrate 1. In this way, when performing film formation on a large size substrate, since it is possible to individually manage the temperature of the plurality of vapor deposition cells 2a, it is possible to eliminate an un-uniformity in the vapor deposition flow. Further, since the substrate 1 and the vapor deposition source 2 can be brought close to each other, it is possible to prevent a low precision in forming a film formation pattern.

Moreover, Japanese Unexamined Patent Application Publication No. 2001-93667 discloses an improved technique which uses a shielding plate formed with a rectangular vapor-deposition window, disposes a vapor deposition source under the shielding plate in a manner such that the vapor deposition source faces the vapor deposition window, followed by moving a substrate (subject to film formation) on the shielding plate with respect to the vapor deposition window, thereby realizing a film formation at a high film formation speed while at the same time ensuring a uniform film thickness.

However, in the prior art disclosed in Japanese Unexamined Patent Application Publication No. 2001-247959, since the respective vapor deposition cells are arranged to be separated from one another at a predetermined pitch p, and since the respective vapor deposition cells are rendered responsible for forming film formation area in accordance with a predetermined film formation distribution perpendicular to the movement of vapor deposition source, film formation areas of vapor deposition cells mutually adjacent with each other in accordance with the pitch p will be overlapped with one another, causing a problem that irregularities will occur and are distributed in thin film M corresponding to the pitch p.

Although the problem discussed above can be avoided by narrowing the pitch p as small as possible, the miniaturization of the pitch p (the width of which depends upon the width of vapor deposition cells) requires arranging many extremely small vapor deposition cells, resulting in a complicated management of the temperature of the respective vapor deposition cells. Besides, there is a limitation in miniaturizing vapor deposition cells, and if the vapor deposition cells are miniaturized, it will be necessary to frequently supplement the film formation material, resulting in a low operation efficiency in film formation.

In addition, if the thickness of deposited film is not uniform, especially when forming an organic layer for organic EL device, the thickness of the formed organic layer in one luminescent area will be different from that of another, hence rendering it impossible to ensure a uniform luminescence or an acceptable color balance.

In deed, the film formation method disclosed in Japanese Unexamined Patent Application Publication No. 2001-93667 disposes a shielding plate for restricting an incident angle between a substrate and film formation sources, in a manner such that a film formation flow emitted from the film formation source is incident in a direction as perpendicular as possible to the substrate so as to inhibit positional deviation and width change of film formation areas. However, since the film formation flow emitted from the film formation source has a film formation distribution also in a direction perpendicular to the longitudinal direction (i.e., the longitudinal direction of the rectangle vapor deposition window) containing the film formation source, a considerable amount of the film formation material will be blocked by the shielding plate and thus will not be utilized in an actual film formation, resulting in a low efficiency in utilizing film formation material. In particular, since an organic compound material for use in forming an organic layer in organic El device is usually expensive, there will be a problem that the manufacturing cost is high.

### SUMMARY OF THE INVENTION

The present invention is to solve the above-discussed problem and it is an object of the invention to provide an improved vacuum film formation apparatus, organic EL panel and method of manufacturing the same, so that when performing film formation on a large size substrate, it is possible to ensure an acceptable film formation precision as well as a uniform film thickness, and that when forming organic EL devices on a large size substrate, it is possible to ensure a uniform luminescence as well as an acceptable color balance. Another object of the present invention is to increase the utilization efficiency of film formation material, thereby reducing the manufacturing cost.

In order to achieve the above objects, the present invention is characterized by at least the following aspects.

According to one aspect of the present invention, there is provided a film formation source for use in a vacuum film formation apparatus wherein a film formation flow consisting of an atom flow or a molecule flow of a film formation material formed by heating and thus sublimating or evaporating the film formation material is emitted to a film formation surface to form a thin film on the film formation surface. The film formation source comprises: a material accommodating unit containing a film formation material; heating means for heating the film formation material contained within the material accommodating unit; a film formation flow control unit provided at an emission outlet of the material accommodating unit for controlling the direction of the film formation flow. Specifically, the film formation flow control unit provides a strong directivity to the film formation flow with respect to a moving direction of the film formation surface relative to the film formation source.

According to another aspect of the present invention, there is provided a vacuum film formation apparatus wherein a film formation flow consisting of an atom flow or a molecule flow of a film formation material formed by heating and thus sublimating or evaporating the film formation material is emitted to a film formation surface to form a thin film on the film formation surface. In detail, the vacuum film formation apparatus has a film formation source comprising: a material accommodating unit containing a film formation material; heating means for heating the film formation material contained within the material accommodating unit; a film formation flow control unit provided at an emission outlet of the material accommodating unit for controlling the direction of the film formation flow. Specifically, the film formation flow control unit provides a strong directivity to the film formation flow with respect to a moving direction of the film formation surface relative to the film formation source.

### BRIEF DESCRIPTION OF THE DRAWINGS

These and other objects and advantages of the present invention will become clear from the following description with reference to the accompanying drawings, wherein:

FIGS. 1A and 1B are explanatory views showing a prior art.

FIG. 2 is an explanatory view showing a film formation source formed according to an embodiment of the present invention.

FIGS. 3A and 3B are explanatory views showing a film formation source formed according to an embodiment of the present invention.

FIGS. 4A and 4B are explanatory views showing a distribution of molecule density (or atom density) of a film formation flow (including a molecule density distribution having a strong directivity and another molecule density distribution having a weak directivity).

FIGS. 5A-5C are explanatory views showing the structure of a film formation source control unit associated with a film formation source, according to an embodiment of the present invention.

FIG. 6 is an explanatory view showing an example of using the film formation source, according to an embodiment of the present invention.

FIG. 7 is an explanatory view showing the structure of luminescent areas of an organic EL panel.

FIG. 8 is an explanatory view showing an example of an organic EL panel manufactured by using a vacuum film formation apparatus formed according to an embodiment of the present invention.

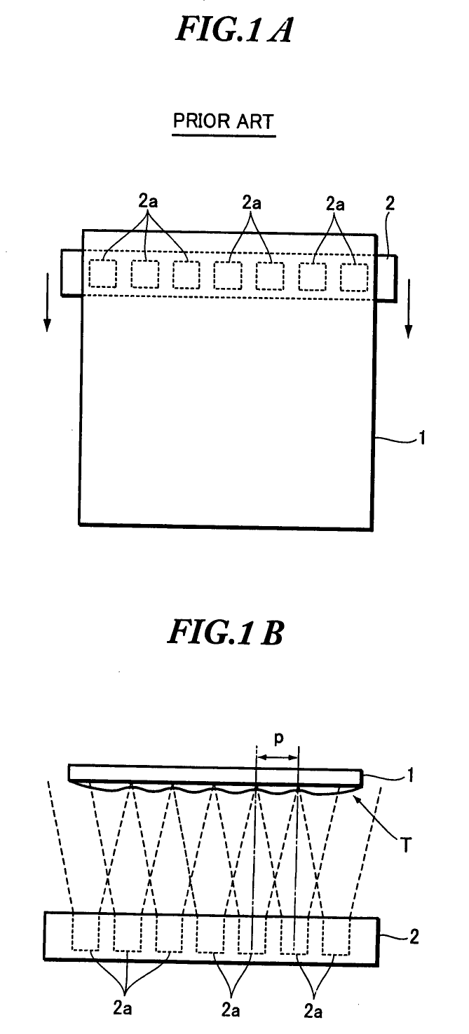

### DETAILED DESCRIPTION OF THE PREFERRED EMBODIMENTS

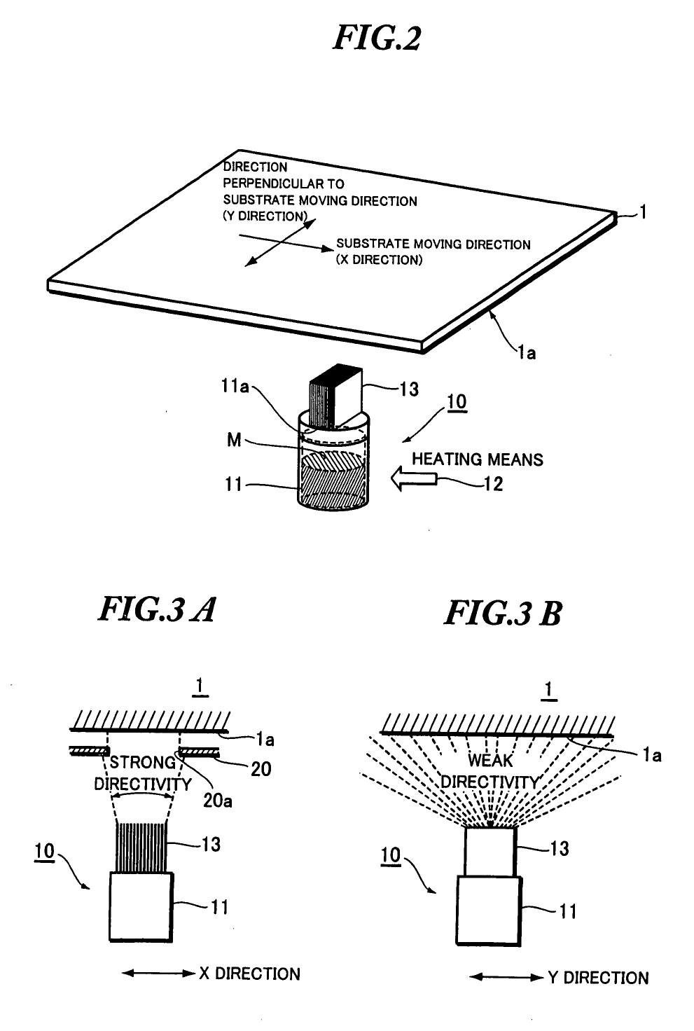

A preferred embodiment of the present invention will be described below with reference to the accompanying drawings. FIG. 2 and FIG. 3 are explanatory views showing a film formation source according to one embodiment of the present invention. As shown, a film formation source 10 comprises a material accommodating unit 11 for accommodating a film formation material M, heating means 12 for heating the film formation material M contained in the material accommodating unit 11, a film formation flow control unit 13 provided at an emission outlet 1a of the material accommodating unit 11 for controlling the direction of a film formation flow. In this way, a film formation flow formed by heating and thus sublimating or evaporating the film formation material M is caused to irradiate a film formation surface 1a of a substrate 1 being moved in X direction, thereby forming a thin film layer on the film formation surface 1a.

Here, the film formation flow control unit 13 operates to provide the film formation flow (an atom flow or molecule flow of the film formation material) with a strong directivity, with respect to the moving direction of the film formation surface 1a relative to the film formation source. Namely, as shown in FIG. 3A, the film formation flow emitted from the film formation flow control unit 13 exhibits a strong directivity with respect to X direction (the moving direction of the substrate), thereby minimizing an amount of film formation material blocked by shielding portions of a mask 20 and thus not passing through openings 20a. Further, as shown in FIG. 3B, the film formation flow emitted from the film formation flow control unit 13 has a relatively weak directivity in Y direction (which is perpendicular to the substrate moving direction) as compared with the strong directivity in X direction.

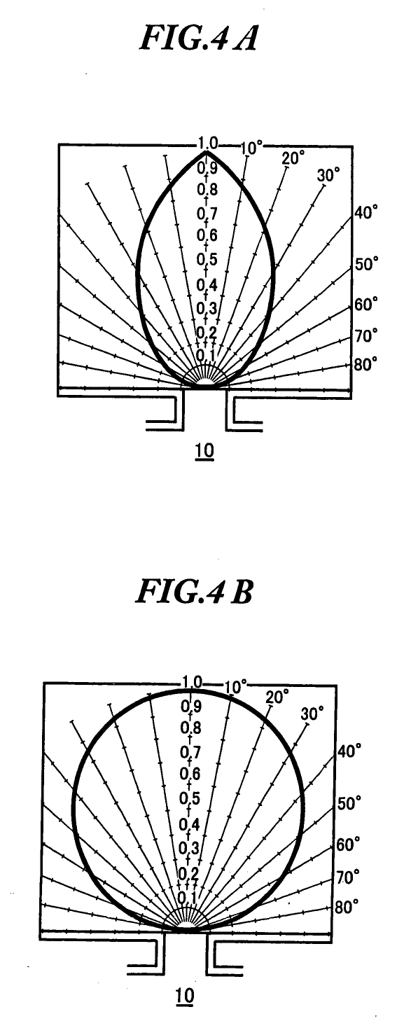

Usually, an equimolecular density plane emitted from a dish-like film formation source exhibits a ball-like distribution shown in FIG. 4B, while an equimolecular density plane emitted from a cylindrical film formation source exhibits a long and narrow Rugby ball-like directivity shown in FIG. 4A. However, so-called strong directivity mentioned in the present embodiment means that an equimolecular density plane (or an atom density plane) of a film formation flow consisting of an atom flow or a molecule flow emitted from the film formation source 10 exhibits a long and narrow Rugby ball-like distribution. In contrast, so-called weak directivity means that an equimolecular density plane (or an atom density plane) of a film formation flow exhibits an approximately spherical distribution. Thus, the film formation source exhibiting different directivities in X, Y directions shows a directivity value which varies continuously from X direction to Y direction.

When using the film formation source 10 described above, the film formation material is emitted in X direction (which is the moving direction of the substrate 1) to the film formation surface 1a with a strong directivity corresponding to the opening 20a of the mask 20, so that it is possible to form a film formation pattern having less film formation deviation (positional deviation of film formation area from right above the opening of the mask), and to ensure an increased utilization ratio of the film formation material. On the other hand, regarding to Y direction which is perpendicular to the moving direction of the substrate 1, since the film formation material is emitted with a weak directivity, it is possible to ensure a uniform film formation with a minimized film thickness change corresponding to certain film formation distribution.

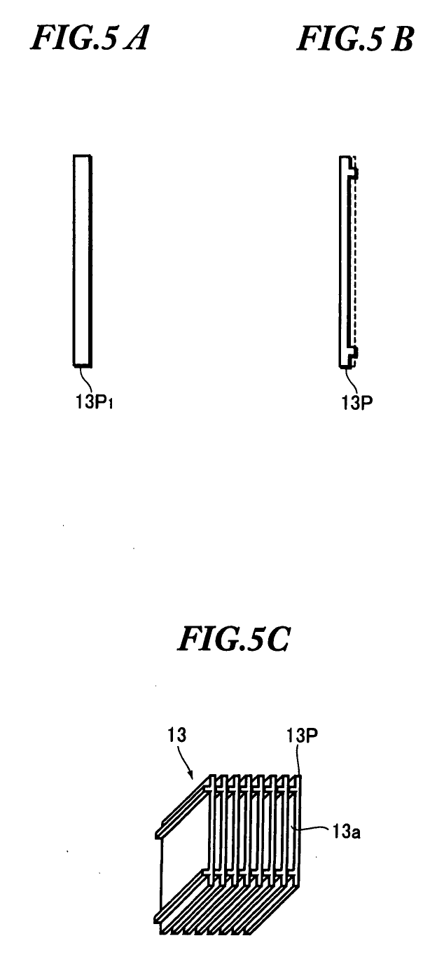

FIG. 5 is an explanatory view showing an example of the structure of the film formation flow control unit 13 of the film formation source 10. As shown, the film formation flow control unit 10 includes a plurality of partition plates 13P separated from one another at a small interval and disposed in Y direction which is perpendicular to the moving direction of the substrate, thereby forming a plurality of emission openings 13a by virtue of the small intervals. Each partition plate 13P can be formed by half-etching a plate member 13P₁ shown in FIG. 5A so as to partially reduce the thickness of the plate member (refer to FIG. 5B). Then, a plurality of partition plates 13P are arranged to be overlapped with one another to form a plurality of slit-like small intervals, thereby forming the plurality of emission openings 13a. However, the film formation flow control unit 13 should not be limited by the above-described structure. In fact, although not shown in the accompanying drawings, it is also possible to form such film formation flow control unit by overlapping a plurality of plates each having bent edge portions, or overlapping a plurality of plates each formed with projections, or by forming a plurality of slits in a cube.

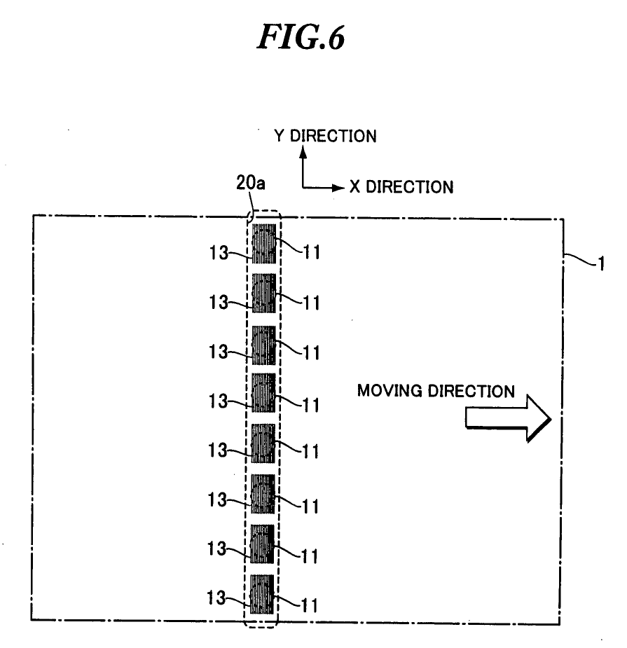

FIG. 6 is an explanatory view showing an example of using the above-described film formation source 10. As shown, a plurality of material accommodating units 11 and their emission outlets are arranged in Y direction which is perpendicular to the substrate moving direction, thereby forming a plurality of film formation flow control units 13 arranged in Y direction. According to this example, using a mask having an elongated hole 20a formed in Y direction has proved to be effective in forming a desired pattern on the film formation surface 1a of the substrate 1. In this way, by moving the substrate 1 in X direction, it is possible to form a plurality of columns of linear patterns at desired positions in Y direction on the film formation surface 1a.

However, the present invention should not be limited by the above-discussed example shown in the accompanying drawings. In fact, it is also possible to form a so-called line source in which material accommodating units 11 are disposed in Y direction so as to form an elongated arrangement, an integral structure in which material accommodating units 11 have been combined with film formation flow control units 13, or a separate structure in which material accommodating units 11 and film formation flow control units 13 are connected with each other through pipes but mutually separated by disposing film formation flow control units 13 within film formation rooms and material accommodating units 11 outside the film formation rooms.

At this time, it is possible to obtain a film formation pattern involving less film formation defect in X direction and ensure a uniform film formation involving less fluctuation in film thickness in Y direction, thereby making it possible to form an appropriate linear film formation patterns even if a substrate 1 subject to film formation has a large size.

Further, there should not be any limitation to the materials forming the material accommodating units 11 and the film formation flow control units 13 in the film formation source 10. For example, it is possible to use nickel, iron, stainless steel, cobalt-nickel alloy, graphite, SiC, Al₂O₃, BN, and magnetic ceramics such as titanium nitride.

Moreover, the heating means 12 may be formed by employing one of various known heating devices involving resistance heating, high frequency heating, laser heating or electron beam heating. Preferably, resistance heating is performed by winding high melting point metal filament or boat-like heating coil, formed by tantalum (Ta), molybdenum (Mo) or tungsten (W), round material accommodating units 11 formed by high melting point oxide such as alumina (Al₂O₃) and beryllia (BeO), thereby making it possible to form heating means capable of heating by flowing an electric current through the heating coil. More preferably, the film formation flow control units 13 are formed by the same material and wound by the same heating coils so that they can be heated in the same manner to the same extent, thereby realizing an appropriate film formation capable of preventing film formation material from adhering to the film formation flow control units 13. Besides, although not shown in the accompanying drawings, it is also possible to provide buffer rooms serving as traps between the material accommodating units 11 and the film formation flow control units 13 so as to remove clustered molecules and prevent film formation defect possibly caused due to spitting.

A vacuum film formation apparatus employing the above-described film formation sources 10 can be formed by providing the film formation sources 10 within a vacuum film formation room, and providing substrate supplying means for moving the substrate 1 with respect to the film formation sources 10 and for successively supplying different substrates. Here, the vacuum film formation room is maintained at a high vacuum condition (104 Pa or less), so that the film formation sources 10 can be heated and molecule flow of film formation material can be sprayed into the film formation room under a high vacuum condition, thereby forming a thin film layer of the film formation material on the substrate 1. In this way, it is possible to perform continuous film formation on a large size substrate or on a plurality of substrates, thereby ensuing a film formation with a high productivity.

In addition, although the above-described embodiment is based on an in-line type vacuum film formation apparatus in which the substrate 1 moves linearly with respect to the film formation sources 10, the present invention should not be limited by this. Actually, it is also possible to provide rotating means for rotating a substrate having a film formation surface with respect to the film formation sources, so as to form a cluster type film formation apparatus offering the same effect as the in-line type vacuum film formation apparatus. At this time, the direction of the strong directivity is preferably arranged to be orthogonal to the radial direction of the rotation.

A vacuum film formation apparatus employing the above-described film formation source 10 is suitable for use in carrying out a method for manufacturing an organic EL panel containing organic EL devices as its display elements. Such an organic EL panel comprises a substrate and organic EL devices formed on the substrate. Each organic EL device includes a first electrode, a second electrode, and at least one organic layer containing at least one organic luminescent layer disposed between the first and second electrodes. The above-described vacuum film formation apparatus can be used in forming at least one sort of film formation material on the substrate so as to form electrodes or organic layer thereon.

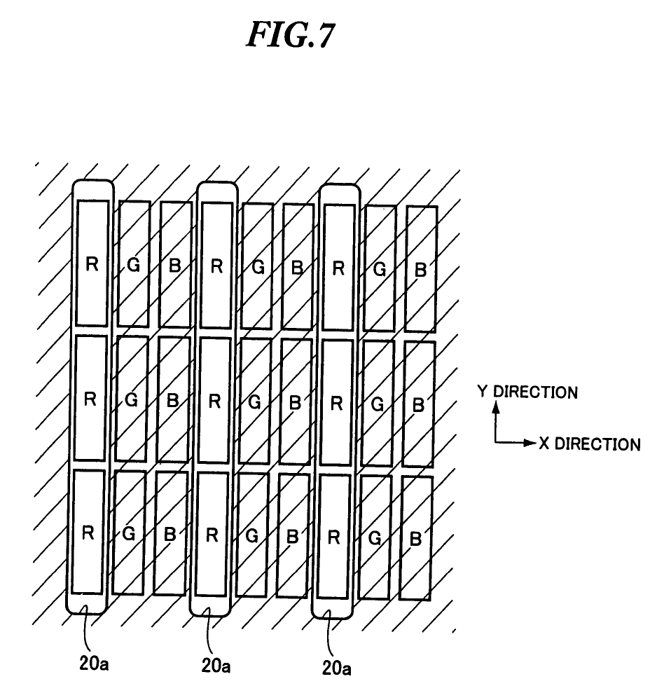

In this way, it is possible to effectively perform film formation of various colors on a panel which performs color display by a plurality of colors (three kinds of colors RGB in an example shown in FIG. 7) of luminescent areas so arranged that each line contains one kind of color. Namely, as shown in FIG. 7, when the openings 20a of a mask are aligned with the lines for respective colors and a discriminated coloring based on film formation is performed, it is possible to realize a film formation with less color deviation by forming patterns involving less film formation defect, thereby making it possible to improve the utilization ratio of film formation material. Moreover, in Y direction containing luminescent areas of an identical color, it is possible to perform a film formation ensuring a uniform thickness by emitting a film formation material with a weak directivity, thereby obtaining an effect of preventing a leak current possibly caused due to a film formation defect.

However, the present invention should not be limited by the above-described organic EL panel for performing color display. In fact, it is also allowed to use a film formation source having a strong directivity in X direction and a weak directivity in Y direction, constantly move the substrate in X direction to form various film layers on the substrate, thereby making it possible to perform a film formation ensuring a uniform film thickness and a high utilization ratio of the film formation material.

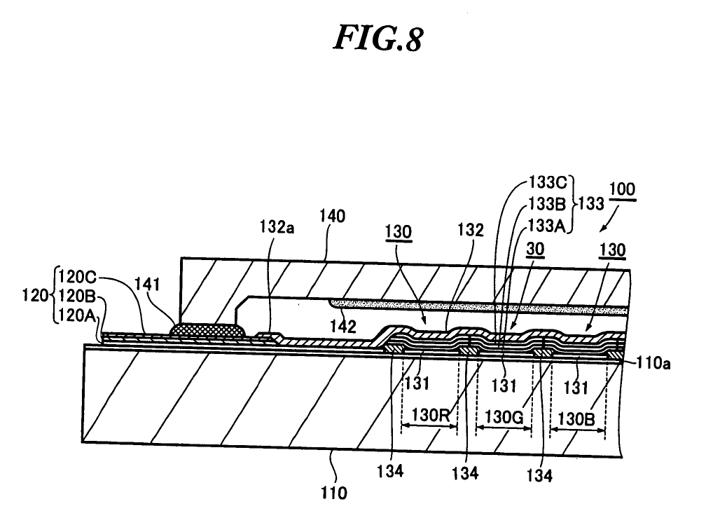

FIG. 8 is an explanatory view showing an example of an organic EL panel manufactured by using the above-described vacuum film formation apparatus.

As shown, an organic EL panel 100 is formed by interposing an organic layer 133 containing an organic luminescent layer between first electrodes 131 on one hand and second electrodes 132 on the other, thereby forming a plurality of organic EL devices 130 on the substrate 110. In an example shown in FIG. 8, a silicone coating layer 110a is formed on the substrate 110, and a plurality of first electrodes 131 consisting of transparent electrode material such as ITO and serving as cathodes are formed on the silicon coating layer 110a. Further, second electrodes 132 consisting of a metal and serving as anodes are formed above the first electrodes 131, thereby forming a bottom emission type panel producing light from the substrate 110 side. Moreover, the panel also contains an organic layer 133 including a positive hole transporting layer 133A, a luminescent layer 133B, and an electron transporting layer 133C. Then, a cover 140 is bonded to the substrate 110 through an adhesive layer 141, thereby forming a sealing space on the substrate 110 and thus forming a display section consisting of organic EL devices 130 within the sealing space.

In the example shown in FIG. 8, the organic EL devices 130 are formed such that the first electrodes 131 are separated by a plurality of insulating strips 134, thereby forming luminescent units (130R, 130G, 130B) under the first electrodes 131. Moreover, a desiccant layer 142 is attached to the inner surface of the cover 140, thereby preventing the organic EL devices 130 from getting deteriorated due to moisture.

Moreover, along the edge of the substrate 110 there is formed a first electrode layer 120A using the same material and the same step as forming the first electrodes 131, which is separated from the first electrodes 131 by the insulating strips 134. Further, on the lead-out portion of the first electrode layer 120A there is formed a second electrode layer 120B containing a metal such as Ag, Cr, Al, and the like, for example, a silver-palladium (Ag—Pg) alloy and forming a low-resistant wiring portion. In addition, if necessary, a protection coating layer 120C consisting of IZO or the like is formed on the second electrode layer 120B. In this way, a lead-out electrode 120 can be formed which consists of the first electrode layer 120A, the second electrode layer 120B, and the protection coating 120C. Then, an end portion 132a of each second electrode 132 is connected to the lead-out electrode 120 within the sealing space.

Here, although the lead-out electrode of each first electrode 131 is not shown in the drawing, it is possible to elongate each first electrode 131 and lead the same out of the sealing space. Actually, such lead-out electrode can also be formed into an electrode layer containing Ag—Pd alloy or the like and constituting a low resistant wiring portion, similar to an example associated with the above-described second electrode 132.

Next, description will be given to explain in detail the organic EL panel 100 and the method of manufacturing the same, according to one embodiment of the present invention.

a. Electrodes

Either the first electrodes 131 or the second electrodes 132 are set as cathode side, while the opposite side is set as anode side. The anode side is formed by a material having a higher work function than the cathode side, using a transparent conductive film which may be a metal film such as chromium (Cr), molybdenum (Mo), nickel (nickel), and platinum (Pt), or a metal oxide film such as ITO and IZO. In contrast, the cathode side is formed by a material having a lower work function than the anode side, using a metal having a low work function, which may be an alkali metal (such as Li, Na, K, Rb, and Cs), an alkaline earth metal (such as Be, Mg, Ca, Sr, and Ba), a rare earth metal, a compound or an alloy containing two or more of the above elements, or an amorphous semiconductor such as a doped polyaniline and a doped polyphenylene vinylene, or an oxide such as Cr₂O₃, NiO, and Mn₂O₅. Moreover, when the first electrodes 131 and the second electrodes 132 are all formed by transparent materials, it is allowed to provide a reflection film on one electrode side opposite to the light emission side.

The lead-out electrodes (the lead-out electrode 120 and the lead-out electrode of the first electrodes) are connected with drive circuit parts driving the organic EL panel 100 or connected with a flexible wiring board. However, it is preferable for these lead-out electrodes to be formed as having a low resistance. Namely, the lead-out electrodes can be formed by laminating low resistant metal electrode layers which may be Ag—Pd alloy or APC, Cr, Al, or may be formed by single one electrode of low resistant metal.

b. Organic Layer

Although the organic layer 133 comprises one or more layers of organic compound materials including at least one organic luminescent layer, its laminated structure can be in any desired arrangement. Usually, as shown in FIG. 8, there is a laminated structure including, from the anode side towards the cathode side, a hole transporting layer 133A, a luminescent layer 133B, and an electron transporting layer 133C. Each of the hole transporting layer 133A, the luminescent layer 133B, and the electron transporting layer 133C can be in a single-layer or a multi-layered structure. Moreover, it is also possible to dispense with the hole transporting layer 133A and/or the electron transporting layer 133C. On the other hand, if necessary, it is allowed to insert other organic layers including a hole injection layer, an electron injection layer and a carrier blocking layer. Here, the hole transporting layer 133A, the luminescent layer 133B, and the electron transporting layer 133C can be formed by any conventional materials (it is allowed to use either a high molecular material or a low molecular material).

With regard to a luminescent material for forming the luminescent layer 133B, it is allowed to make use of a luminescence (fluorescence) when the material returns from a singlet excited state to a base state or a luminescence (phosphorescence) when it returns from a triplet excited state to a base state.

c. Covering Member (Covering Film)

Further, the organic EL panel 100 according to the present invention is a panel formed by tightly covering organic EL devices 130 with a covering member 140 made of metal, glass, or plastic. Here, the covering member may be a piece of material having a recess portion (a one-step recess or a two-step recess) formed by pressing, etching, or blasting. Alternatively, the covering member may be formed by using a flat glass plate and includes an internal covering space M to be formed between the flat glass plate and the support substrate by virtue of a spacer made of glass (or plastic).

In order to tightly seal the organic EL devices 130, it is also possible for the covering member 140 to be replaced by a sealing film to cover the organic EL devices 130. The covering film can be formed by laminating a single layer of protection film or a plurality of protection films, and is allowed to be formed by either an inorganic material or an organic material. Here, an inorganic material may be a nitride such as SiN, AlN, and GaN, or an oxide such as SiO, Al₂O₃, Ta₂O₅, ZnO, and GeO, or an oxidized nitride such as SiON, or a carbonized nitride such as SiCN, or a metal fluorine compound, or a metal film, etc. On the other hand, an organic material may be an epoxy resin, or an acryl resin, or a paraxylene resin, or a fluorine system high molecule such as perfluoro olefin and perfluoro ether, or a metal alkoxide such as CH₃OM and C₂H₅OM, or a polyimide precursor, or a perylene system compound, etc. In practice, the above-mentioned lamination and material selection can be carried out by appropriately designing the organic EL devices.

d. Adhesive Agent

An adhesive agent forming the adhesive layer 141 may be a thermal-setting type, a chemical-setting type (2-liquid mixture), or a light (ultraviolet) setting type, which can be formed by an acryl resin, an epoxy resin, a polyester, a polyolefine. Particularly, it is preferable to use an ultraviolet-setting epoxy resin adhesive agent which is quick to solidify without a heating treatment.

e. Desiccating Material

Desiccating material 142 may be a physical desiccating agent such as zeolite, silica gel, carbon, and carbon nanotube; a chemical desiccating agent such as alkali metal oxide, metal halogenide, peroxide chlorine; a desiccating-agent formed by dissolving an organic metallic complex in a petroleum system solvent such as toluene, xylene, an aliphatic organic solvent and the like; and a desiccating agent formed by dispersing desiccating particles in a transparent binder such as polyethylene, polyisoprene, polyvinyl thinnate.

f. Various Types of Organic EL Display Panels

The organic EL panel 100 of the present invention can have various types without departing from the scope of the invention. For example, the light emission type of an organic EL device 130 can be a bottom emission type emitting light from the substrate 110 side, or a top emission type emitting light from a side opposite to the substrate 110. Moreover, the EL display panel may be a single color display or a multi-color display. In practice, in order to form a multi-color display panel, it is allowed to adopt a discriminated painting method or a method in which a single color (white or blue) luminescent layer is combined with a color conversion layer formed by a color filter or a fluorescent material (CF manner, CCM manner), a photograph breaching method which realizes a multiple light emission by emitting an electromagnetic wave or the like to the light emission area of a single color luminescent layer, or SOLED (transparent Stacked OLED) method in which two or more colors of unit display areas are laminated to form one unit display area.

According to the above-described embodiment of the present invention, a film formation flow consisting of a molecule flow or an atom flow of a film formation material can be formed by heating and thus sublimating or evaporating the film formation material. Such a film formation flow is then emitted towards a film formation surface of a substrate so as to form a thin film on the substrate. A film formation source of a vacuum film formation apparatus for forming the thin film comprises a material accommodating unit for accommodating a film formation material, heating means for heating the film formation material contained in the material accommodating unit, a film formation flow control unit provided at emission outlet of the material accommodating unit for controlling the direction of the film formation flow. The film formation flow control unit provides a strong directivity to the film formation flow with respect to the moving direction of the film formation surface relative to the film formation source. Therefore, when forming linear film patterns perpendicular to the moving direction of the film formation surface, it is possible to form film patterns involving less film formation defect in a direction perpendicular to their longitudinal direction, and thus realize a film formation having a high utilization ratio of the film formation material.

Moreover, since the film formation flow control unit can ensure a weak directivity in a direction perpendicular to the moving direction of the film formation surface, it is possible to form the aforementioned linear film patterns having a uniform thickness in their longitudinal direction.

Furthermore, with regard to the film formation sources formed according to the above-described embodiment of the present invention, since a plurality of material accommodating units and a plurality of material emission outlets are arranged in a direction perpendicular to the moving direction of the film formation surface, it is possible to form linear film patterns involving less film formation defect in a direction perpendicular to their longitudinal direction on a large size film formation surface (without causing any film formation un-uniformity in the longitudinal direction), thus ensuring a film formation with a high utilization ratio of film formation material.

The film formation flow control units, each of which includes a plurality of partition plates separated from one another at an extremely small interval, are disposed in a direction perpendicular to the moving direction of the film formation surface, thereby forming a plurality of film formation flow emission openings by virtue of thus formed extremely small intervals. In this way, it is possible to emit film formation flows having a strong directivity in the direction of these extremely small intervals by adjusting film formation rate, but emit film formation flows having a weak directivity in a direction parallel to the partition plates.

Moreover, with regard to the vacuum film formation apparatus equipped with such film formation sources, since there is provided substrate supply means for successively supplying a plurality of substrates (each having a film formation surface) with respect to the film formation sources, it is possible to perform a continuous film formation, thereby realizing a film formation operation with a high productivity.

In this way, using the film formation sources and vacuum vapor deposition apparatus containing such film formation sources formed according to the above-described embodiment of the present invention, it is possible to manufacture an organic EL panel including a substrate, a least a pair of electrodes formed on the substrate, and a plurality of organic layers including an organic luminescent layer and interposed between the electrodes. In particular, when forming the electrodes or linear film patterns on the organic layers, as described above, it is possible to form linear film patterns involving less film formation defect in a direction perpendicular to their longitudinal direction (without causing any film formation un-uniformity in the longitudinal direction), thus ensuring a film formation with a high utilization ratio of film formation material.

In particular, when manufacturing an organic EL panel capable of performing a color displaying, it is possible to inhibit color deviation in film formation patterns of various colors, thereby producing (at a high productivity) a high quality organic EL panel involving less leak current by virtue of a uniform film thickness.

In this way, the above-described film formation source, vacuum film formation apparatus, organic EL panel and method of manufacturing the same are suitable for carrying out a film formation operation on a substrate having a relatively large size, thus ensuring a film formation with an acceptable pattern formation precision and a uniform film thickness. Moreover, in forming organic EL devices on a substrate having a relatively large size, it is possible to ensure a uniform luminescence performance and an acceptable color balance, thereby improving a utilization ratio of film formation material and thus reducing the manufacturing cost.

While there has been described what are at present considered to be preferred embodiments of the present invention, it will be understood that various modifications may be made thereto, and it is intended that the appended claims cover all such modifications as fall within the true spirit and scope of the invention.

What is claimed is:

1. A method of manufacturing an organic EL panel formed by interposing at least one organic layer containing at least one organic luminescent layer between a pair of electrodes mounted on a substrate, said method comprising:
forming said electrodes or said at least one organic luminescent layer in a vacuum film formation apparatus,
wherein said vacuum film formation apparatus comprises a film formation source and a vacuum film formation room,
wherein said film formation source includes at least one material accommodating unit containing a film formation material, heating means for heating the film formation material contained in the at least one material accommodating unit, a film formation flow control unit provided at an emission outlet of the at least one material accommodating unit for controlling the direction of a film formation flow,
wherein said vacuum film formation room includes substrate supplying means for moving the substrate with respect to the film formation source and for successively supplying different substrates, said vacuum film formation room being so provided that a film formation flow including an atom flow or a molecule flow of a film formation material formed by heating and thus sublimating or evaporating the film formation material is emitted to a film formation surface of a substrate being moved in an X direction,
wherein the film formation flow control unit provides a predetermined directivity to the film formation flow with respect to the X direction,
wherein the film formation flow control unit controls the film formation flow in a manner such that the flow receives a weaker directivity in a direction (Y direction) perpendicular to the X direction than in said X direction,
wherein said film formation source includes a plurality of material accommadating units and a plurality of emission outlets arranged in said Y direction.

2. The method according to claim 1, wherein a mask having an elongated hole arranged in Y direction as well as a substrate, are moved in the X directon.

3. The method according to claim 2, wherein said elongated hole is used in a discriminated coloring step for forming films of various colors in an organic EL panel capable of color displaying based on lines of different colors.
